(19) United States
(12) Patent Application Publication
(10) Pub. No.: US 2020/0045846 A1
(43) Pub. Date: Feb. 6, 2020

(54) SYSTEM FOR COMPENSATION OF EXPANSION/CONTRACTION OF A COOLING MEDIUM INSIDE A SEALED CLOSURE

(71) Applicant: CommScope Connectivity Belgium BVBA, Kessel-Lo (BE)

(72) Inventors: Nicolas DE JAEGERE, Schilde (BE); Eddy Luc CAMS, Bilzen (BE); Julian S. MULLANEY, Raleigh, NC (US)

(73) Assignee: CommScope Connectivity Belgium BVBA, Kessel-Lo (BE)

(21) Appl. No.: 15/738,455

(22) PCT Filed: Jun. 30, 2016
(86) PCT No.: PCT/EP2016/065345

§ 371 Date: Dec. 20, 2017

Related U.S. Application Data
(60) Provisional application No. 62/186,915, filed on Jun. 30, 2015.

(51) Int. Cl. H05K 7/20; H02G 3/08; G02B 6/44; H02G 3/16; H02G 3/03

(52) U.S. Cl. CPC H05K 7/20236; H02G 3/088; G02B 6/4448; H02G 3/03; H02G 3/16; H05K 7/20272; H02G 3/083

(57) ABSTRACT

A closure (100) protects telecommunications circuitry from environmental factors. The closure includes a base (128) having a sidewall (134) extending upwardly from a bottom (118), the sidewall (134) defining at least one cable port (122). The closure also includes a cover (126) that attaches to the base (128) to close an interior (130) of the closure (100). In addition, electronic circuitry (132) disposed within the interior (130) of the closure (100). Encompassing the electronic circuitry (132) is a cooling medium (138) dispersed through the interior (130). Further, a pressure regulating device (136) is placed in the interior (130) to maintain a viable internal operating pressure for the closure.

### CROSS-REFERENCE TO RELATED APPLICATION

This application claims the benefit of U.S. Patent Application Ser. No. 62/186,915, filed on Jun. 30, 2015, the disclosure of which is incorporated herein by reference in its entirety.

### BACKGROUND

Fiber to the distribution point (FTTdp) is a fiber-optic based communication delivery network in which optical fibers are run in an optical distribution network from a central office to locations (i.e., distribution points) located near subscribers. Electrical cables complete the network, extending from the distribution points to the subscribers (e.g., to Optical Network Terminals or other subscriber equipment). The optical signals carried by the optical fibers are converted into electrical signals, which are carried by the electrical cables and the remaining distance to the subscribers.

Closures that hold electronic circuitry for transmitting or converting optical signals and electrical signals sometimes generate significant amounts of heat that can inhibit the operation of the electronic circuits within the closure.

Improvements are desired.

### SUMMARY

The present disclosure relates to an internal pressure regulating closure that holds electronic circuitry to convert or transmit optical signals.

One aspect of the present disclosure relates to a sealed telecommunications closure for telecommunications circuitry comprising. The closure can include a housing that has a base and a cover that cooperate to define an interior; electronic circuitry located within the housing, the optical to electrical converter can be active electronic circuitry; a cooling liquid dispersed through the interior of the housing to cool electronics therein; and an expansion structure integrated with the housing to accommodate expansion of the cooling liquid caused by temperature spikes and to prevent breakage of a seal within the closure.

In accordance with an aspect of the disclosure, a closure for circuitry is disclosed. The closure for circuitry includes a base that has a sidewall extending upwardly from a bottom. The sidewall defines at least one cable port. The closure also includes a cover that attaches to the base to close an interior of the closure. The closure also includes electronic circuitry disposed within the interior of the closure. The electronic circuitry, in one example, is active electronic circuitry. The closure includes a cooling medium that encompasses the electronic circuitry. In addition, the closure comprises an internal pressure regulating device. In some examples, the pressure regulating device can comprise one of the following: an elastic material, an air piston, and a mechanical spring. In some examples, the closure can also comprise a seal that is placed between the cover and the base, wherein the seal prevents fluids from entering the enclosure.

In some examples, the cable port or ports can pass through any portion of the closure. One example is a two passage tube, such as a double channeled tube, that can be inserted in one of the ports to facilitate filling the interior with the cooling medium and also removing any air from the interior.

In accordance with an additional aspect of the disclosure, a method for assembly of the internal pressure regulating sealed closure includes providing a closure including a cover and a base having a sidewall extending upwardly from a bottom. The sidewall defines at least one cable port. The method includes placing electronic circuitry within the interior of the closure, the electronic circuitry being active. The method further includes securing the cover to the base to close an interior of the closure.

The method can also include inserting a two passage tube into the at least one cable port. Additionally, a cooling medium is dispersed into the interior of the closure through a first passage of the tube. As an appropriate amount of cooling medium is dispersed into the cavity, air is removed from the interior of the closure through a second passage of the tube. The method can also include sealing the tube.

Various cable ports can be provided, such as one or more, for incoming and outgoing cables, including fiber cables, copper cables, and/or hybrid cables.

A variety of additional aspects will be set forth in the description that follows. The aspects can relate to individual features and to combinations of features. It is to be understood that both the foregoing general description and the following detailed description are exemplary and explanatory only and are not restrictive of the broad inventive concepts upon which the embodiments disclosed herein are based.

### BRIEF DESCRIPTION OF THE DRAWINGS

The following drawings are illustrative of particular embodiments of the present disclosure and therefore do not limit the scope of the present disclosure. The drawings are not to scale and are intended for use in conjunction with the explanations in the following detailed description. Embodiments of the present disclosure will hereinafter be described in conjunction with the appended drawings, wherein like numerals denote like elements.

FIG. 1 illustrates a schematic view of a closure in an underground environment, according to one embodiment of the present disclosure;

FIG. 2 illustrates a first perspective view of the closure, according to one embodiment of the present disclosure;

FIG. 3 illustrates an exploded perspective view of the closure of FIG. 2;

FIG. 4 illustrates a perspective view of the base of the closure of FIG. 2;

FIG. 5 illustrates a flowchart depicting a process for sealing the closure;

FIG. 6 schematically illustrates an example closure configured for use in a switching system in accordance with the principles of the present disclosure;

FIG. 7 schematically illustrates the closure of FIG. 6 in another switching system in accordance with the principles of the present disclosure;

FIG. 8 is a perspective view of the closure of FIG. 6 shown in a closed position;

FIG. 9 illustrates a perspective view of the closure of FIG. 8 including a circuit board covered with cooling liquid, and a cover of the closure exploded outwardly from a base;

FIG. 10 illustrates a perspective view of the closure of FIG. 9 depicting remote copper switches in accordance with the principles of the present disclosure; and

FIG. 11 illustrates a perspective view of the closure of FIG. 10 with the remote copper switches positioned inside of the closure in accordance with the principles of the present disclosure.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

The closure disclosed is configured to house active electronic circuitry related to fiber optic signal transmission or conversion. The closure also is configured to environmentally seal (e.g., a water-tight seal, a vapor-tight seal, etc.) the electronic circuitry from an external environment. Additionally, the closure is configured to be corrosion resistant. The closure can also house active electronic circuitry related to copper signal transmission where no fiber optic signals are present.

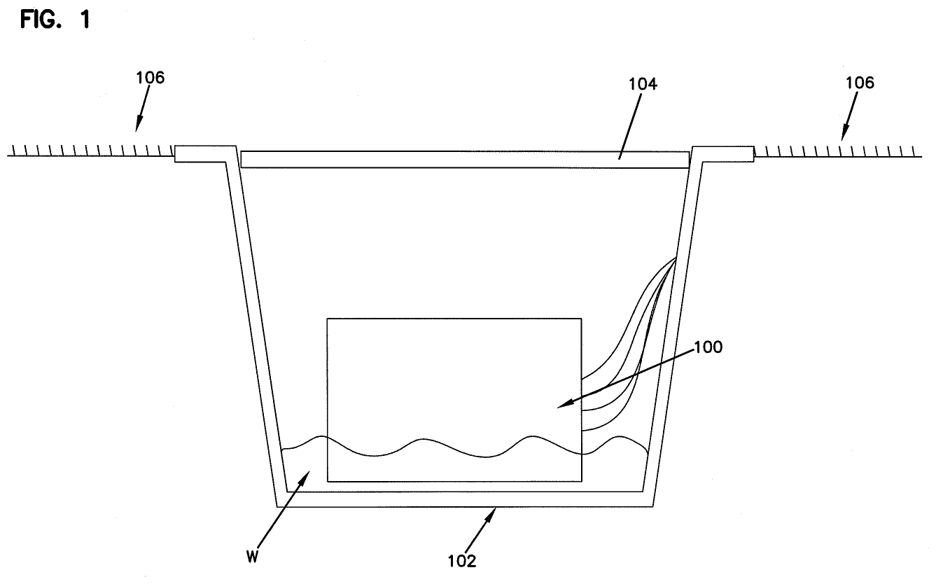

FIG. 1 illustrates an example environment including an example closure 100. The closure 100 is depicted in an underground container 102. The underground container 102 includes a lid 104 that is generally flush with the ground surface 106. Because the underground container 102 is positioned below the ground surface 106, the container underground 102 is susceptible to flooding by water, especially rain water. As shown, water W can pool within the underground container 102 and partially or totally submerge equipment within the underground container 102, including the closure 100.

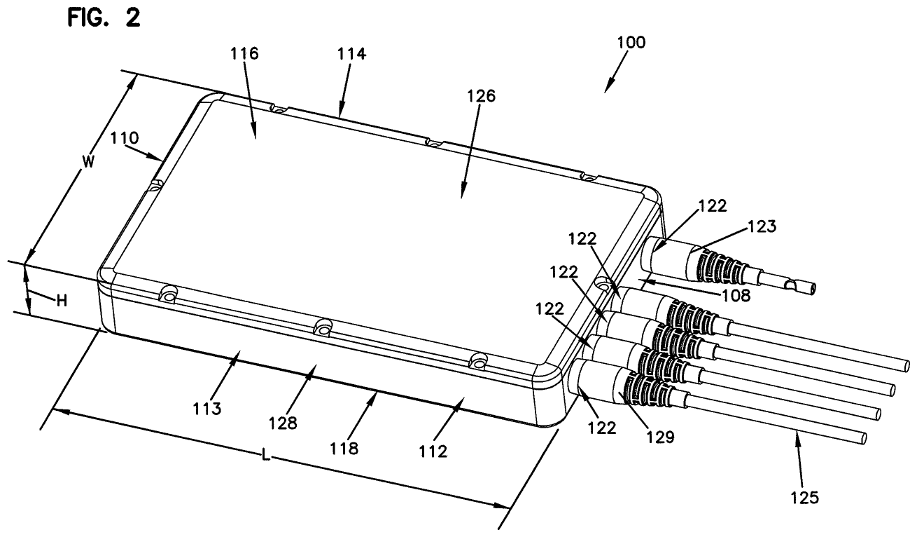

FIGS. 2-4 show perspective views of the closure 100. The closure 100 extends along a length L between a first end 108 and a second end 110, along a width W between a first side 112 and a second side 114, and along a height H between a top 116 and a bottom 118. Additionally, the closure 100 includes at least one port 122.

The port 122 is configured to receive a cable 125. In some embodiments, the cable 125 is a fiber optic cable. In other embodiments, the cable 125 is a copper cable. The closure 100 can include a plurality of ports 122 in some embodiments. In the depicted embodiment, the ports 122 are configured to be positioned at the first end 108 of the closure 100. However, it is contemplated that the ports 122 could be positioned at a side 112, 114 or at the second end 110 of the closure 100 or other locations, or in combinations of locations. In some embodiments, the port 122 is configured to be positioned at an angle with respect to a side and an end of the closure. In the depicted embodiment, the closure can comprise a plurality of ports 122 in a line on end 108.

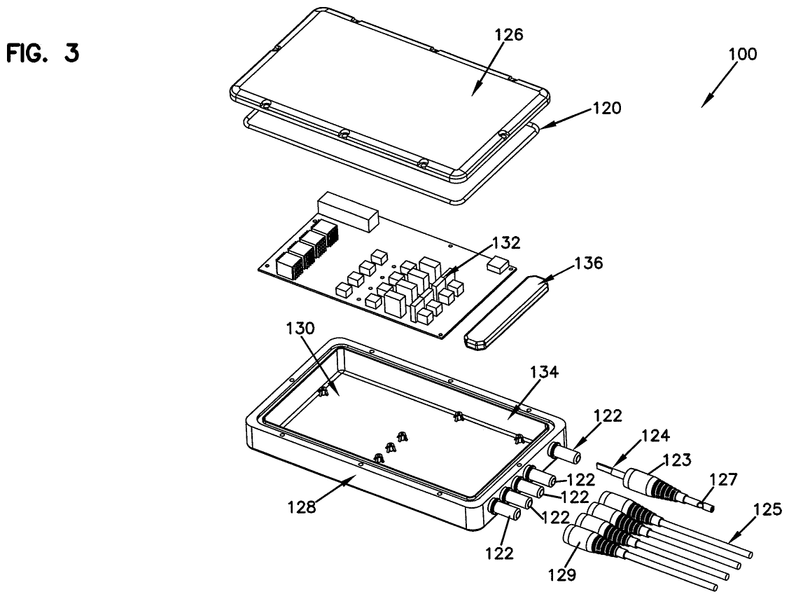

FIG. 3 shows an exploded view of the closure 100. The closure 100 includes a housing 112 having a cover 126, a base 128, an interior 130, a heat generating element such as electronic circuitry 132, and the ports 122. The cover 126 and the base 128 cooperate to define the interior 130. Within the interior 130, the electronic circuitry 132 is disposed. Attached to the base 128 is at least one port 122 for cables. The closure 100 is water-tight at the various joints and intersections of parts.

In the example shown, the base 128 includes a sidewall 134 extending upward from the bottom 118. The cover 126 attaches to the sidewall 134 opposite the bottom 118. The base 128 and/or cover 126 can be configured to disperse heat generated by the electronic circuitry 132 within the interior 130 of the closure 100. In transferring the heat generated, the closure can facilitate transferring heat away from the electronic circuitry 132 to the environment surround the closure 100. For example, the base 128 and/or cover 126 can be formed of a thermally conductive material (e.g., a metal). In an example, the base 128 and/or cover 126 can be formed of die cast aluminum. In other examples, the base 128 and/or cover 126 can be formed of thermally conductive plastics.

In one embodiment, the closure 100 can further comprise a seal 120. When securing the closure, the seal 120 can be placed between the cover 126 and the base 128 such that seal 120 provides an additional measure of protection against outside elements. In a particular embodiment, the seal 120 can aid in providing an air tight and water tight barrier. The seal can be comprised of plastic, rubber, or silicone material that can prevent liquids from entering the closure and exiting the closure.

The electronic circuitry 132 can be disposed within the interior 130. The electronic circuitry 132 is active (i.e., powered) and produces heat during normal operation. The electronic circuitry 132 is configured to radiate heat in the interior 130 of the closure 100. In some embodiments, the electronic circuitry 132 includes a circuit board with components mounted thereto.

FIG. 3 also shows a pressure regulating device 136. As discussed earlier, the ability to use the closure in an external environment requires protection against the environment, which can be use by properly sealing the closure. In addition, to insure proper function of the components in the closure, the environment inside the closure must also be considered. In an embodiment, the heat generated by the electronic circuitry 132 be can dissipated by a cooling medium 138 contained within interior 130. The cooling medium 138 acts as both a cooling agent and a heat transfer medium from the electronic circuitry 132. In other embodiments, the cooling medium acts as a barrier for humidity and other environmental factors such as air, moisture, excessive temperatures, and excessive temperature ranges. Introducing environment factors to the electronic components can cause malfunctions in the components. The cooling medium 138 and the pressure regulating device 136 regulate the heat and pressure in interior 130.

During operation, the cooling medium 138 is subjected to temperature changes that cause pressure to increase and decrease inside the closure 100. Heat generated by the internal components is transported through the cooling medium 138 to the inside of housing 112 of the closure 100. Subsequently, the generated heat is transferred from the closure 100 to the external environment. The cooling medium 138 creates an even surface temperature on the closure body. This even surface temperature reduces the thermal hot-spots and reduces overall temperature of the closure, improving thermal exchange. In example embodiments, the cooling medium 138 can be made out of natural oil, petrochemical oil, or other synthetic materials. In addition, the cooling medium 138 can possess other characteristics that make it viable for use with electric components such as being non-corrosive, non-electrically conductive and nonreactive with the structure and function of the internal components.

When the cooling medium 138 possesses the physical characteristic of low compressibility, an increase in internal pressure occurs when the cooling medium is heated. As stated earlier, the heat is generated from the activity of the enclosed electronic circuitry 132. To counteract the increase in internal pressure, a pressure regulating device 136 can be used. A purpose of the pressure regulating device 136 is to ensure that the pressure inside the closure 100 does not exceed the maximum allowable internal operating pressure. The pressure regulating device 136 can be any device that stores potential energy generated by the pressure of the cooling medium. In addition, the pressure regulating device 136 can release the stored potential energy when the cooling system no longer exerts pressure on the pressure regulating device 136. Examples of the pressure regulating device 136 can include any pressure storing system internal to the closure 100 such as an elastic material, air piston, or mechanical springs.

In certain implementations, the electronic circuitry 132 is configured to convert between optical signals and electrical signals. In such implementations, optical signals carried over an optical fiber cable can be converted to electrical signals by the electronic circuitry 132, and the electrical signals can be carried over the electrical conductor(s). Accordingly, signals carried between a central office and a subscriber can be carried over optical fibers along a majority of the network to closure 100 and carried over electrical conductors only over short distances between the closure 100 and the subscriber.

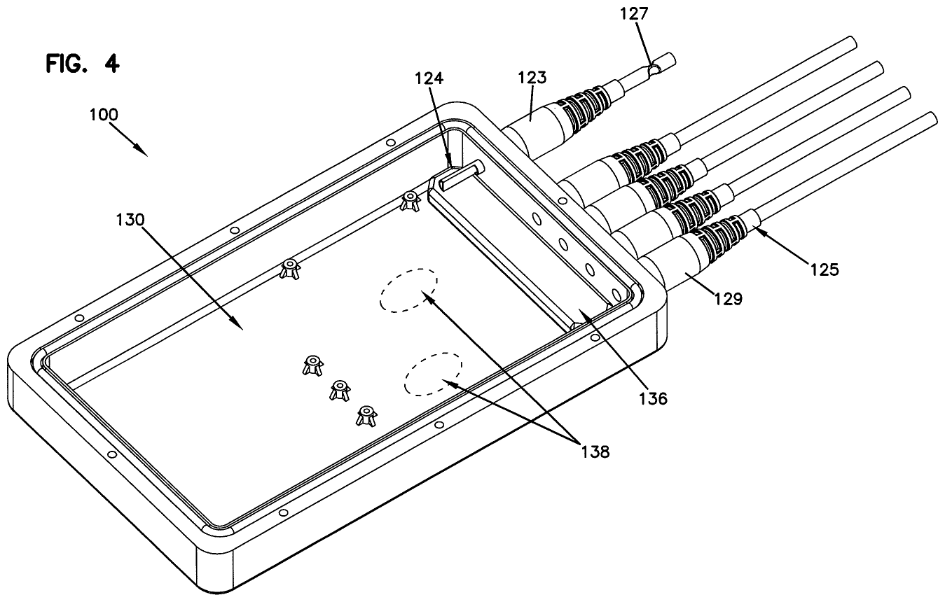

FIG. 4 shows an embodiment of FIG. 2 with a plurality of ports 122. One of the ports in the plurality of ports can be dedicated to providing a pathway to introduce the cooling medium 138 to the closure 100. In this embodiment, a fill plug 123 is provided. Fill plug 123 includes a two passage tube 124 that can be connected into one of the ports 122. The tube 124 in the example includes two parallel channels. One channel can be used to introduce the cooling medium into the closure. A second channel in the dual sided tube can be used to evacuate air from a sealed chamber. A seal 127 is then provided on tube 124 after closure 100 is filled with the cooling medium 138.

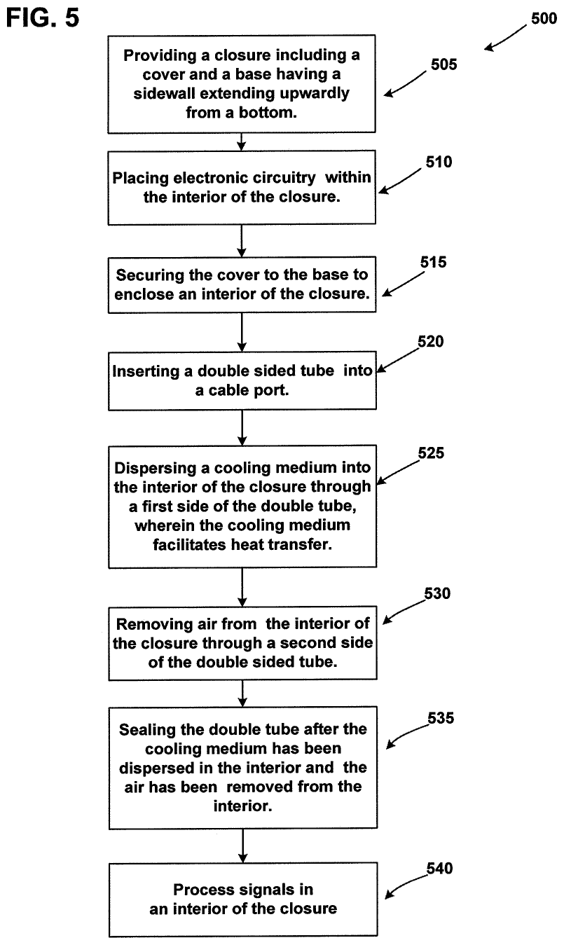

FIG. 5 illustrates an overview process of sealing the electronic components in the closure. In the process 500 of assembling the closure, the process flows to operation 505 where a closure is provided. The cover 126 and base 128 can be configured such that that when the cover 126 is placed on the base 128 an interior space is defined. Flowing to operation 510, an element can be placed in the interior. In an example embodiment, the element can be an electronic circuitry 132. While in operation, the electronic circuitry 132 can generate heat. In order to ensure that the generated heat does not inhibit the function of the enclosed electrical circuitry, the heat can be transferred from the circuit to the closure and finally to the environment surrounding the closure.

Moving to operation 515, the cover 126 is secured to the base 128. The cover can be attached to the base by an attachment device such as screw, bolt, adhesive, etc. Reducing the encroachment of environmental factors into the interior 130 can be aided by including a sealing mechanism. The seal 120 can be placed between cover 126 and base 128 which can decrease air and fluid permeability between the joints of the cover 126 and base 128. Transitioning to operation 520, a tube 124 can be placed into a port 122. The port 122 can be defined by an aperture in a wall of the closure. In one embodiment, the tube 124 can be double sided where the tube has two parallel channels. Accordingly, both channels can serve a purpose. For example, in moving to operation 525, a cooling medium 138 can be introduced to the interior 130 through one channel of the double sided tube, and air can be evacuated from the other channel.

While the appropriate amount of cooling medium 138 has been dispersed into the interior 130, the process can include operation 530 where the second channel can be used to remove air from the interior 130. Removing the air decreases the environmental factors that can interact with the electronic circuitry 132 during operation and allows the interior 130 to fill with the cooling medium 138. Operation 535 illustrates sealing the tube 124 after the cooling medium has been dispersed and the air has been removed from the interior. In other embodiments the tube can be mechanically sealed or hermetically sealed using heat. At operation 540, telecommunications signals are processed by the interior components in closure 100.

One aspect of the closure 100 includes: a closure for regulating internal heat generation including an internal pressure regulating device 136.

Another aspect of the closure 100 includes: a base 128 having a sidewall 134 extending upwardly from a bottom 118, such that the closure defines an interior 130; and a cover 126 that attaches to the base 128, and a pressure regulating device 136 located in the interior 130.

A further aspect of the closure 100 includes: at least one cable port 122; a cooling medium 138 dispersed through the interior 130; and a pressure regulating device 136 located in the interior 130, wherein the device is configured to react to a pressure changes in the housing, wherein the pressure change is exerted by the cooling medium 138.

A further aspect of the closure 100 includes: electronic circuitry 132, such that electronic circuitry 132 is orientated in the interior 130 and encompassed by the cooling medium 138.

In one example, one port 122 includes a fill plug 123, one port 122 includes a fiber cable, and one port 122 includes a copper cable.

Connector devices 129 connect cables 125 to closure 100. Connector devices can provide sealing and pull protection. Cables 125 extend into closure 100 and connect to the electronic circuitry 132 and/or to other cables.

Another aspect of the present disclosure relates to one or more environmentally sealed closures adapted for housing equipment (switching circuitry, optical-to-electrical conversion circuitry, etc.) used in systems for readily facilitating making telecommunications service upgrades or other changes in service in the field. In certain examples, system upgrades can include switching from an electrical feed line coupled to a service provider's central office to a fiber optic feed line coupled to the service provider's central office.

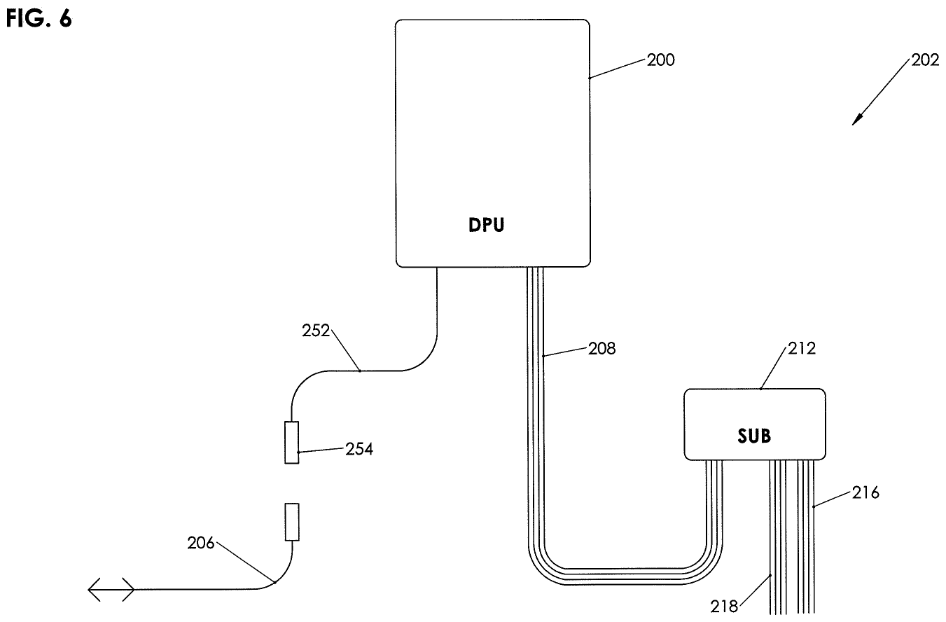

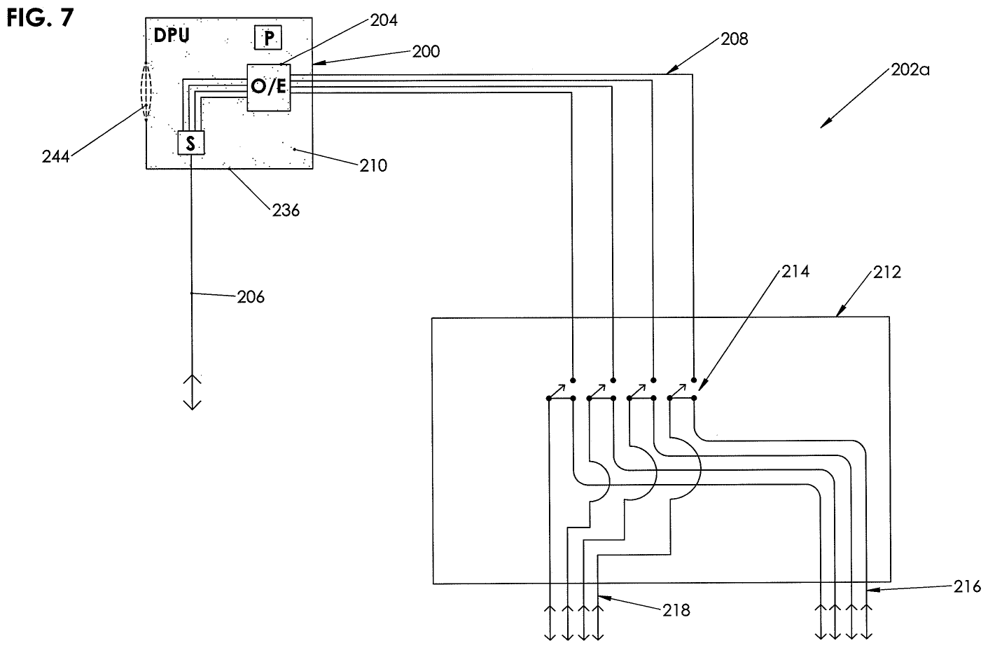

Referring to FIG. 6, another example closure 200 is illustrated for use in a system 202 for upgrading telecommunications service in the field. The example closure 200 depicted is a distribution point unit (DPU). While the example embodiments discussed herein are with reference to a distribution point unit (DPU) type closure 200, other types of closures may be used. The closure 200 is illustrated and described in more detail with reference to FIGS. 7-11.

The closure 200 can hold electronic circuitry 204 (e.g., opto-electrical conversion electronics) (see FIG. 7) for converting optical signals to electrical signals and for converting electrical signals into optical signals (i.e., conversion circuitry). The closure 200 is configured to receive both an optical fiber carrying the optical signals and an electrical conductor carrying the electrical signals. The optical signals are transmitted to and from the closure 200 by an optical fiber line 206 and the electrical signals are transmitted to and from the closure 200 by an upgrade line(s) 208 including at least one twisted wire pair. Where more than one upgrade line 208 is provided, the lines 208 can be encased within a common jacket (i.e., tube, cable jacket, sleeve) or routed as separate twisted wire pairs. The closure 200 can include a passive optical power splitter S to split the optical fiber line 206 within the closure 200 before entering the electronic circuitry 204, although alternatives are possible. The closure 200 is also configured to environmentally seal (e.g., a water-tight seal, a vapor-tight seal, etc.) the electronic circuitry 204 from an external environment.

Referring to FIG. 7, the example closure 200 is depicted in another system 202a. The system 202a can also include a switching and termination enclosure 212 that has a housing that contains switching circuitry 214. The switching and termination enclosure 212 can include an overmold made of a plastic resin material. The switching circuitry 214 can be connected to a subscriber line 216 including at least one twisted wire pair and also can be connected to the upgrade line 208. The switching circuitry 214 can further be connected to a service provider basic line 218 including at least one twisted wire pair. The switching circuitry 214 is operable in a first state where subscriber line 216 is connected to the service provider basic line 218 such that a first service (e.g., a basic service) is provided to the subscriber. The switching circuitry 214 is also operable in a second state where the subscriber line 216 is connected to the upgrade line 208 such that the subscriber is disconnected form the first service and connected to the upgrade line 208 such that a second service (e.g., UDSL, G. FAST, an upgraded service such as a faster service that may include extended fiber optic connectivity) is provided to the subscriber.

The example closure 200 and the switching and termination enclosure 212 can each include environmentally sealed protective housings. The closure 200 can be factory assembled with the protective housing and all cable entrance locations sealed. In certain examples, the protective housing of the closure 200 is not intended or configured to be opened in the field. The switching and termination enclosure can have a protective housing designed to be re-enterable in the field. Example configurations for the closure 200 are disclosed by U.S. Provisional Patent Application Nos. 61/135,478; 62/155,944; 62/186,915; and 62/057,540, which are all hereby incorporated by reference in their entireties. Example switching circuit and power routing configurations for the system 202a are disclosed by U.S. Provisional Patent Application No. 62/194,140 which is hereby incorporated by reference in its entirety. Examples of ruggedized and sealed connectors and adapters that can be incorporated on stub cables of the closures or onto the housings of the closures or elsewhere in the system are disclosed by U.S. Pat. Nos. 7,744,288; 7,686,519 and U.S. patent application Ser. No. 14/360,383 which are all hereby incorporated by reference in their entireties.

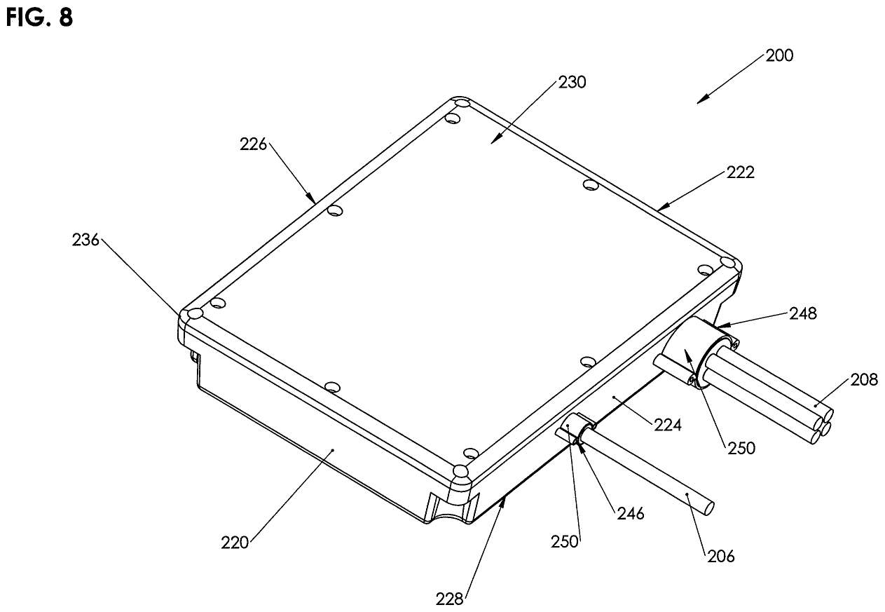

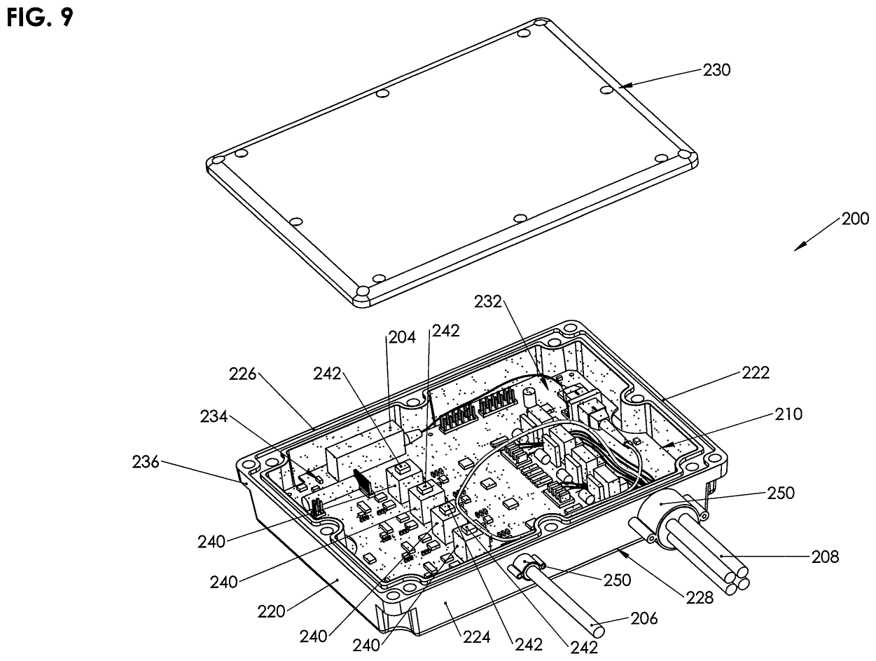

Referring to FIGS. 8 and 9, the example closure 200 can include a housing 236 that has a first end 220, an opposite second end 222. The housing 236 of the closure 200 includes a first side 224 and an opposite second side 226 that each extend between the first and second ends 220, 222. The closure 200 includes a base 228 and a cover 230 that cooperate to define an interior 232. The switching circuitry 214 is disposed within the interior 232 of the closure 200. For example, a circuit board 234 can be disposed within the interior 232 of the closure 200. The circuit board 234 can include the opto-electrical conversion electronics 204.

The base 228 and/or cover 230 can be configured to disperse heat generated by the electronic circuitry 204. For example, closure 200 can be a rigid container where the base 228 and/or cover 230 can be formed of a thermally conductive material (e.g., a metal). In an example, the base 228 and/or cover 230 can be formed of Al Die cast. In other examples, the base 228 and/or cover 230 can be formed of thermally conductive plastics (e.g., polypropylene). The closure 200 may be thin so that it can still radiate heat as aluminum. However, a system 202 including an upgraded, faster, service with extended fiber optic connectivity may need a closure design that can handle increased heat loads of a G. fast chipset.

The closure 200 in accordance with the present disclosure can be filled with cooling liquid 210 (e.g., cooling medium) to help dissipate heat generated by the electronic circuitry 204 and to help prevent arching. The cooling liquid 210 can help to eliminate localized hot spots in the closure 200.

As used herein, the term, “liquid,” is defined as including cooling oils, hydraulic fluids, or other liquids having heat transfer properties suitable for cooling.

The cooling liquid 210 can be an incompressible fluid, for example, oil. In one example, the cooling liquid 210 can be a natural oil, petrochemical oil, and/or a synthetic material, although alternatives are possible. Rather than have a closure filled with air, which acts as an insulator, oil can be used to help eliminate air voids. No air voids means that there would be no pressure differential. Thus, the closure 200 can be submerged and there would be no force that exists to drive water into the closure 200. Such a design can allow the closure 200 to be made with alternate materials that are not bulky, rigid, or complex, but rather lighter and easy to manufacture. The oil can be supplied to the closure 200 through an injection port (e.g., one way valve; fill plug), although alternatives are possible. The closure 200 can further include a bleed valve (not shown) that can be used to bleed air out of the closure 200.

The cooling liquid 210 can also be compatible with both a plastic closure and the electronics housed therein. The cooling liquid 210 (i.e., oil, a better conductor of heat than air) can help provide better thermal management and heat dissipation compared to typical thermal conduction methods of using clay. By eliminating the thermal bottleneck of the interior air space by including the cooling liquid 210, the closure 200 can still radiate enough heat to keep peak temperatures lower despite being made of a poor conductor, such as plastic.

In certain examples, the closure 200 can include a pump P (see FIG. 7) to circulate the cooling liquid 210 within the closure 200. The pump P can be arranged and configured to power on when a temperature threshold is reached. The pump P encourages internal circulation of liquid between the interior surface of the housing 236 and any heat generating circuitry so that heat can more readily be transferred out of the housing 236. The pump P circulates liquid within the housing 236 to help prevent localized hot spots around the heat generating circuitry.

In one example, the circuit board 234 can include one or more transformer relays 240 that can each have heat transfer fins 242 that are exposed to the cooling liquid 210 to help dissipate heat to the cooling liquid 210. Other heat generating elements (e.g., chips, optical/electrical converter, etc.) on the circuit board 234 can also include heat transfer fins 242 to help dissipate heat. In other examples, chips or active components may have integrated temperature sensors within the closure 200 for measuring temperature spikes.

In certain examples, the closure 200 can include an integral expansion structure 244 (e.g., rubber membrane, disc, circular corrugating member, ribs, etc.)(see FIG. 7). The integral expansion structure 244 may be integrally formed as one single piece with the housing 236 of closure 200, although alternatives are possible. In one example, the integral expansion structure 244 can be positioned on the base 228, although alternatives are possible. For example, the integral expansion structure 244 can be positioned on the cover 230. In still other examples, the integral expansion structure 244 may be positioned on both the base 228 and the cover 230.

The integral expansion structure 244 can allow the rigid closure 200 to expand and contract due to the cooling liquid 210 heating within the sealed closure 200. The integral expansion structure 244 can expand to accommodate expansion of the cooling liquid 210 caused by temperature rises or spikes, which can help to prevent the breakage of a seal 238 located within the closure 200 as the cooling liquid 210 heats up. The integral expansion structure 244 can be made of an elastic material such that once the temperature is reduced, the integral expansion structure 244 can contract back to its original state.

In other examples a piezo-electric fan (not shown) may be used to management temperature spikes in the example of an air filled DPU. The piezo-electric fan would power on when internal temperatures hit a predetermined threshold limit, but remain off at all other times. In other examples, a fluid paddle (not shown) can be used to increase internal convection in the example of a liquid filled/cooled DPU.

When securing the closure 200, the seal 238 can be placed between the cover 230 and the base 228 such that seal 238 provides an additional measure of protection against outside elements. In a particular embodiment, the seal 238 can aid in providing an air tight and water tight barrier. The seal can be comprised of plastic, rubber, or silicone material that can prevent liquids from entering the closure and exiting the closure.

The optical fiber line 206 can be routed into the closure 200 through a first port 246 and the upgrade line(s) 208 can be routed out of the closure 200 through a second port 248. The first and second ports 246, 248 can each include a sealing arrangement 250. In certain examples, the sealing arrangement 250 can be a fluid seal arranged and configured about the optical fiber line 206 and the upgrade lines 208.

In certain examples, the closure 200 can include: 1) a fiber optic stub 252 (see FIG. 6) having a ruggedized single or multi-fiber connection port or connector 254 for connecting to the optical fiber line 206; or 2) a ruggedized fiber optic adapter (not shown) mounted to the closure for receiving a ruggedized connector of the optical fiber line 206; or 3) a fiber optic stub (not shown) terminated by a non-ruggedized single or multi-fiber connector (not shown); or 4) a non-connectorized stub (not shown) that is spliced to the optical fiber line 206; or 5) an optical fiber (not shown) that is routed between the closure 200 and the switching and termination closure 212. The optical fiber can be adapted for connection to the optical fiber line 206 at the switching and termination enclosure 212 can be factory sealed relative to the closure 200 so as to be part of a factory integrated stub assembly that is routed from the closure 200 to the switching and termination closure 212.

In certain examples, the optical fiber signals pass through the switching and termination closure 212 before being routed to the closure 200. In certain examples, the upgrade line(s) 208 and the optical fiber are routed between the closure 200 and the switching and termination closure 212 by a hybrid fiber optic/electrical cable (not shown). In other examples, separate cables route the optical fiber and the upgrade line(s) 208 between the closures 200, 212.

The upgrade line(s) can carry electrical power from the switching and termination closure 212 to the closure 200 for use in powering the optical-to electrical circuitry 204. Power can be provided to the switching and termination enclosure 212 from the subscriber locations via the subscriber lines 216.

In certain examples, the switching and termination enclosure 212 includes: 1) a fiber optic stub having a ruggedized single or multi-fiber connection port or connector for connecting to the optical fiber line 206 (not shown); or 2) a ruggedized fiber optic adapter (not shown) mounted to the switching and termination enclosure 212 for receiving a ruggedized connector (not shown) of the optical fiber line 206 and the non-ruggedized connector (not shown) of the optical fiber stub (not shown); or 3) a fiber optic stub terminated by a non-ruggedized single or multi-fiber connector (not shown); or 4) a non-connectorized stub that is spliced to the optical fiber line (not shown).

In certain examples, the switching and termination enclosure 212 and the closure 200 are positioned together within a further environmentally sealed housing (not shown).

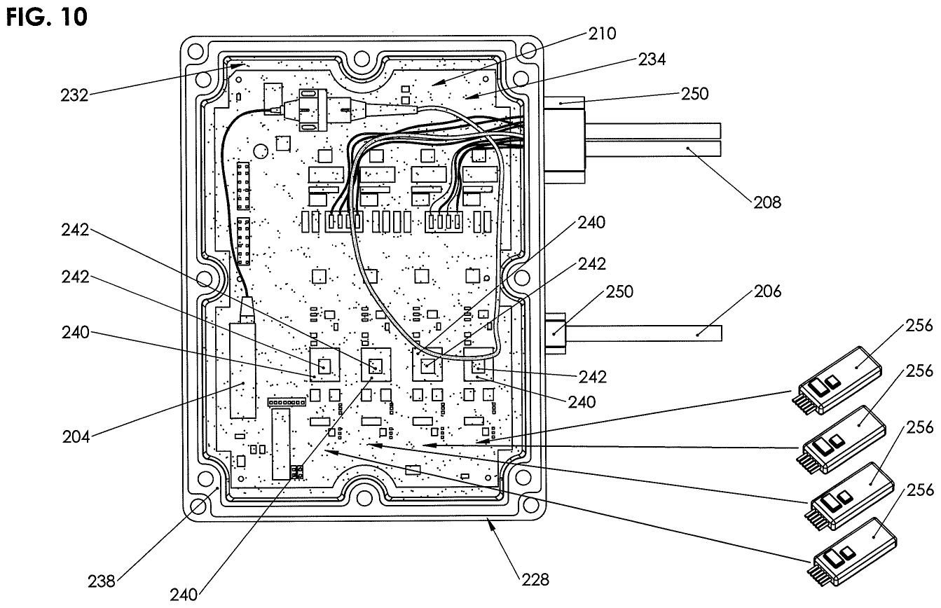

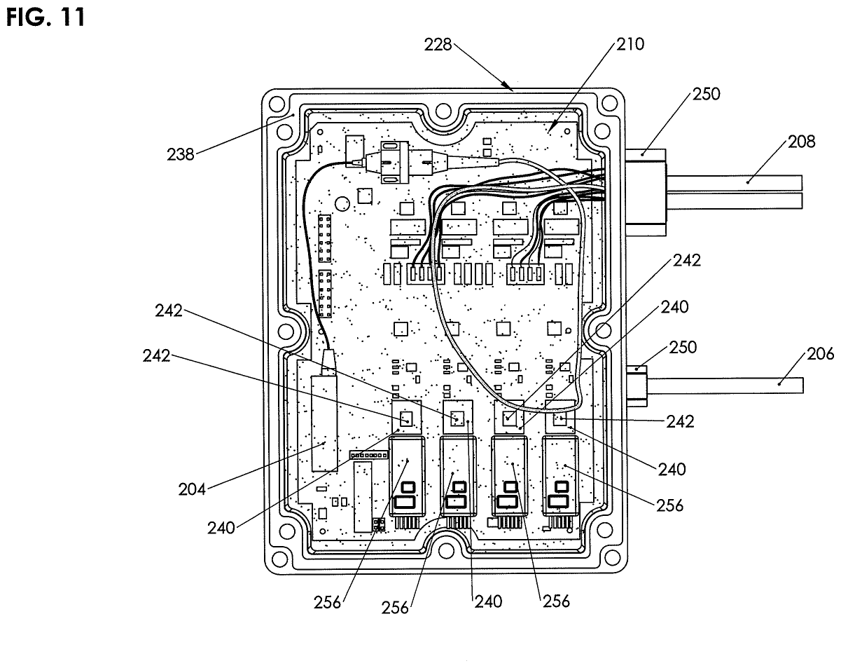

In one example, one or more remote copper switches 256 (RCS)(see FIGS. 10-11) that define the switching circuitry 214 can be integrated onto the circuit board 234 inside of the closure 200, although alternatives are possible. The RCS can be surrounded by the cooling liquid 210 within the interior 232 of the closure 200. In the example depicted, there are four remote copper switches 256, although alternatives are possible. Passive electronics of each remote copper switch 256 can be placed inside of the closure 200. Thus, the individual RCS switching circuitry 214 can be combined with the circuit board 234 instead of separately in each RCS. Thus, small printed circuit boards that reside in the RCS are no longer needed. Nor is there any need for complicated overmolding of the RCS circuitry. By eliminating these parts and integrating their function onto the circuit board 234, there can be obvious cost and logistics advantages.

From the forgoing detailed description, it will be evident that modifications and variations can be made without departing from the spirit and scope of the disclosure.

The various embodiments described above are provided by way of illustration only and should not be construed to limit the claims attached hereto. Those skilled in the art will readily recognize various modifications and changes that may be made without following the example embodiments and applications illustrated and described herein, and without departing from the true spirit and scope of the following claims.

### PARTS LIST

100 closure
102 underground container
104 lid
106 ground surface
108 first end
110 second end
112 housing
113 first side
114 second side
116 top
118 bottom
120 seal
122 port
123 fill plug
124 two passage tube
125 cable
126 cover
127 seal
128 base
129 cable connection device
130 interior
132 electronic circuitry
134 sidewall
136 pressure regulating device
138 cooling medium
200 closure
202 system
204 electronic circuitry
206 optical fiber line
208 upgrade line
210 cooling liquid
212 switching and termination enclosure
214 switching circuitry
216 subscriber line
218 service provider basic line
220 first end
222 second end
224 first side
226 second side
228 base
230 cover
232 interior
234 circuit board
236 housing
240 transformer relays
242 heat transfer fins
244 integral expansion structure
246 first port
248 second port
250 sealing arrangement
252 fiber optic stub
254 connector
256 remote copper switch

1. A sealed telecommunications closure for telecommunications circuitry comprising:
a housing including a base and a cover that cooperate to define an interior;
electronic circuitry located within the housing, the electronic circuitry being active electronic circuitry;
cooling liquid dispersed through the interior of the housing to cool electronics therein; and
an expansion structure integrated with the housing to accommodate expansion of the cooling liquid caused by temperature spikes and to prevent breakage of a seal within the closure.

2. The closure of claim 1, wherein the electronic circuitry includes an optical to electrical converter.

3. The closure of claim 1, wherein the cooling liquid comprises one of the following: a natural oil, petrochemical oil, and synthetic material.

4. The closure of claim 1, further comprising an optical input that connects with a remote copper switch to provide service upgrades.

5. The closure of claim 1, wherein the remote copper switch is positioned within the housing of the closure.

6. A telecommunications closure for telecommunications circuitry comprising:
a base having a sidewall extending upwardly from a bottom, the sidewall defining at least one cable port;
a cover that attaches to the base and a seal orientated between the base and cover, to seal an interior of the closure;
a cooling medium dispersed through the interior;
a pressure regulating device located within the interior;
electronic circuitry disposed within the interior of the closure, the electronic circuitry being active electronic circuitry;
a plurality of cable ports to access the interior.

7. The closure of claim 6, wherein the pressure regulating device comprises at least one of the following: an elastic material, an air piston, and a mechanical spring.

8. The closure of claim 6, wherein the closure further comprises a fill plug including a two passage tube, such that the tube comprises two parallel channels, wherein one of the channels is configured to disperse the cooling medium into the interior of the closure and a second channel configured to remove air from the closure.

9. The closure 100 of claim 6, wherein the plurality of cable ports includes a cooling medium fill port, and a plurality of remaining ports for cables.

10. The closure of claim 6, wherein the cooling medium is non-corrosive, non-electrically conductive, and nonreactive to an element orientated in the closure.

11. The closure of claim 10, wherein the cooling medium comprises one of the following: a natural oil, petrochemical oil, and synthetic material.

12. A telecommunications closure for regulating internal heat generation comprising:
a housing wherein the housing comprises a cover and a base such that the housing defines an interior;
a cooling medium dispersed through the interior;
a heat generating element, such that heat generating element is orientated in the interior and encompassed by the cooling medium; and
a pressure regulating device located in the interior, wherein the device is configured to react to a pressure change in the housing, wherein the pressure change is exerted by the cooling medium.

13. The closure of claim 12, wherein the housing further comprises a seal such that the seal is orientated between the base and cover, wherein the seal is configured to prevent water from entering the interior.

14. The closure of claim 12, wherein the heat generating element comprises electronic circuitry disposed within the interior of the housing, the electronic circuitry being active electronic circuitry.

15. The closure of claim 12, wherein the pressure regulating device is configured to react to pressure changes by preventing the housing from exceeding a maximum internal pressure when the housing is sealed.

16. The closure of claim 12, wherein the pressure regulating device comprises at least one of the following: an elastic material, an air piston, and a mechanical spring.

17. The closure of claim 12, wherein the cooling medium of claim 7 wherein the cooling medium is non-corrosive, non-electrically conductive, and nonreactive to an element orientated in the closure.

18. The closure of claim 12, wherein the housing further comprises a port, wherein the port facilitates dispersing the cooling medium into the interior.

19. The closure of claim 18, wherein the port further comprises a two passage tube configured to be integrated into the port, such that the tube comprises two parallel channels, wherein one of the channels is configured to disperse the cooling medium into the interior of the closure and a second channel configured to remove air from the housing.

20. A method for assembling a telecommunications closure, the method comprising:
providing a closure including a cover and a base having a sidewall extending upwardly from a bottom, wherein the sidewall defines at least one cable port and wherein the closure defines an interior;
placing electronic circuitry within the interior of the closure, the electronic circuitry being active electronic circuitry;
securing the cover to the base to enclose an interior of the closure;
inserting a two passage tube into the at least one cable port;
dispersing a cooling medium into the interior of the closure through a first passage of the tube, wherein the cooling medium facilitates heat transfer; and
removing air from the interior of the closure through a second passage of the tube.

21. The method of claim 20, wherein securing the cover to the base comprises attaching the cover and the base such that a securing mechanism between the cover and the base provides a barrier to environmental factors.

22. The method of claim 20, wherein the tube is sealed after the cooling medium has been dispersed in the interior and the air has been removed from the interior.

23. The method of claim 21, wherein the tube is sealed hermetically by thermal sealing of the tubing.

24. The closure and methods of claim 6 further comprising cables extending to and from the closure.

25. The closure and methods of claim 6 further comprising an underground container for receiving the closure.

26. A telecommunications closure comprising:
a body or housing including at least an external surface, and an interior;
a cooling medium dispersed through the interior;
a pressure regulating device located within the interior;
electronic circuitry located within the interior, the electronic circuitry being active electronic circuitry;
a plurality of cable ports to access the interior wherein one port includes a fill plug for the cooling medium, wherein at least one port includes a fiber cable, and wherein at least one port includes a copper cable.
